(19) United States
(12) Patent Application Publication
(10) Pub. No.: US 2014/0009163 A1
(43) Pub. Date: Jan. 9, 2014

(54) APPARATUS FOR TESTING AN ARC FAULT DETECTOR

(71) Applicant: Patrick Ward, Ballinasloe (IE)

(72) Inventor: Patrick Ward, Ballinasloe (IE)

(73) Assignee: ATREUS ENTERPRISES LIMITED, Ballinasloe (IE)

(21) Appl. No.: 14/006,238

(22) PCT Filed: Jan. 23, 2012
(86) PCT No.: PCT/EP2012/050935

§ 371 Date: Sep. 19, 2013

(30) Foreign Application Priority Data
Apr. 8, 2011 (IE) S2011/0168

(51) Int. Cl. G01R 35/00

(52) U.S. Cl. CPC G01R 35/00
USPC 324/424

(57) ABSTRACT

An apparatus for testing an arc fault detector comprises a housing (30) having an ac power input plug (32) and an ac power output socket (34), the plug being connected to supply ac power to the socket via electrical supply conductors (L, N) inside the housing. The socket (34) allows connection of an external appliance (36) to the housing for receiving power from the plug (32) through the internal supply conductors. An arc generator (100) inside the housing is connected between the plug (32) and the socket (34). The arc generator comprises at least one pair of contacts and means to vibrate the contacts alternately open and closed.

This application is a 35 USC 371 national phase filing of PCT/EP2012/050935, filed Jan. 23, 2012, which claims priority to Irish national application 52011/0168 filed Apr. 8, 2011, the disclosures of which are incorporated herein by reference in their entireties.

### FIELD OF THE DISCLOSURE

This invention relates to an apparatus for testing an arc fault detector.

### BACKGROUND

Arcing is a normal function when switching loads on or off. Such normal arcing occurs with switches and electrical equipment and is usually harmless. As a result it rarely results in a hazardous condition. On the other hand, arc fault conditions can arise anywhere along a circuit or installation which can give rise to high and sustained levels of arcing which can result in electrical fires, and it is desirable to detect and eliminate such arcing faults quickly and effectively.

There is a requirement in UL1699 for detection of two types of arc fault current-series arc fault currents and parallel arc fault currents.

The conditions under which each of these types of arc faults can occur are represented schematically in FIGS. 1A and 1B.

In the case of series arcing, FIG. 1A, a break occurs along the length of a conductor resulting in arcing between the two broken ends of the conductor. However, a load must be connected so as to complete a circuit and enable the arcing current to flow.

In the case of parallel arcing, FIG. 1B, a breakdown in insulation occurs between two conductors, causing arcing across the conductors. One of the conductors may be the earth conductor. In this case, regardless of whether or not a load current is already flowing in the circuit, an additional arcing current will flow in the circuit during the arc fault condition because of the additional current path created by the arc fault.

In both case, such arcing will generate combustion and heat which could give rise to electrical fires. Arc fault detectors (AFDs) are intended to provide protection against such faults, and such devices are described in patent application nos. S2010/0361 and S2010/0534, which are incorporated herein by reference in their entireties.

AFDs are required to detect series and parallel arc fault currents, and it is generally accepted that detection of series arc fault currents is the more difficult of the two because the arcing current is always limited by a load whereas parallel arc fault currents can be substantially greater and easier to detect.

Two critical problems encountered with AFDs in practice are nuisance tripping and masking. In the case of nuisance tripping the AFD trips when operating a load which can produce arcing, e.g. vacuum cleaners, etc. In the case of masking, the AFD fails to trip under a fault condition when an appliance is connected but trips when the appliance is not connected. This problem is caused by the appliance masking the arc fault current signature which is normally detected by the AFD, and once the appliance is switched off the AFD detects the arc current signature. The problem of masking is largely dependent on the arc current detection technique used in the AFD.

AFDs are fitted with a test button to enable the user to test the device after installation. However, the test button can only generate pulses or signals which are detected by the AFD and cause it to trip automatically, but such testing means is not truly representative of an arc fault condition. AFD testers are readily available on the market to enable electricians to test the AFD, but these devices also generate pulses or signals which are not truly representative of an arc fault condition. Furthermore, AFD designs vary considerably with the result that conventional AFD testers may be compatible with some AFDs whilst being incompatible with others. As a result an electrician may need to use different AFDs testers for different AFD designs. Given that in all cases the AFD tester does not produce actual arcing currents, there is always some doubt as to the efficacy of existing AFD test devices.

### SUMMARY

It is an object of the invention to provide an improved AFD tester.

According to the invention there is provided an apparatus for testing an arc fault detector, comprising a housing having an ac power input device connected to supply ac power to electrical conductors inside the housing, and an arc generator inside the housing connected to at least one of the conductors, the arc generator comprising at least one pair of contacts and means to vibrate said contacts alternately open and closed to generate arcing.

The arc generator may comprise a loose electrical connection and means to vibrate said connection.

In such a case the means to vibrate said connection may comprise a mechanical oscillator operated by at least one electromagnetic winding.

The mechanical oscillator may comprise two electromagnetic windings which are energised alternately to drive a ferromagnetic member alternately in opposite directions.

Alternatively, the mechanical oscillator may comprise an electromagnetic winding which is intermittently energised to drive a ferromagnetic member in one direction and a resilient device to return the ferromagnetic member in the opposite direction between successive energisations of the electromagnetic winding.

The arc generator may alternatively comprise a pair of contacts which are caused to vibrate alternately open and closed by repeated energisation of an electromagnetic winding.

In certain embodiments the arc generator is connected in series with one of the conductors inside the housing to simulate a series arc fault.

In other embodiments the arc generator is connected across a pair of conductors inside the housing to simulate a parallel arc fault.

Preferably the vibration means is arranged to vibrate the contacts at the supply frequency.

In order to test an AFD on a dc system the housing may have externally accessible terminals and the arc generator is also connected across said terminals.

Preferably the power input device comprises an electrical plug.

Preferably, too, the housing further has an output device allowing connection of an external appliance for receiving power from the input device through the internal conductors.

In such a case the power output device may comprise an electrical socket.

### BRIEF DESCRIPTION OF THE DRAWINGS

Embodiments of the invention will now be described, by way of example, with reference to the accompanying drawings, in which:

FIGS. 1A and 1B, previously described, are schematic diagrams showing how series and parallel arc faults arise.

FIG. 2 is a diagram of an arc generator used in embodiments of the invention.

FIG. 2A is a detail of FIG. 2 taken on the line 2A-2A.

FIG. 3 is a schematic diagram of an apparatus according to a first embodiment of the invention, designed to simulate a series arc fault.

FIGS. 4 to 8 show alternative constructions of arc generator 100 which could be used in the embodiment of FIG. 3, in place of the arc generator of FIG. 2.

FIG. 9 is a circuit diagram of an apparatus according to a further embodiment of the invention, designed to simulate a parallel arc fault.

In the various figures of the drawings the same or equivalent components have been given the same references.

### DETAILED DESCRIPTION

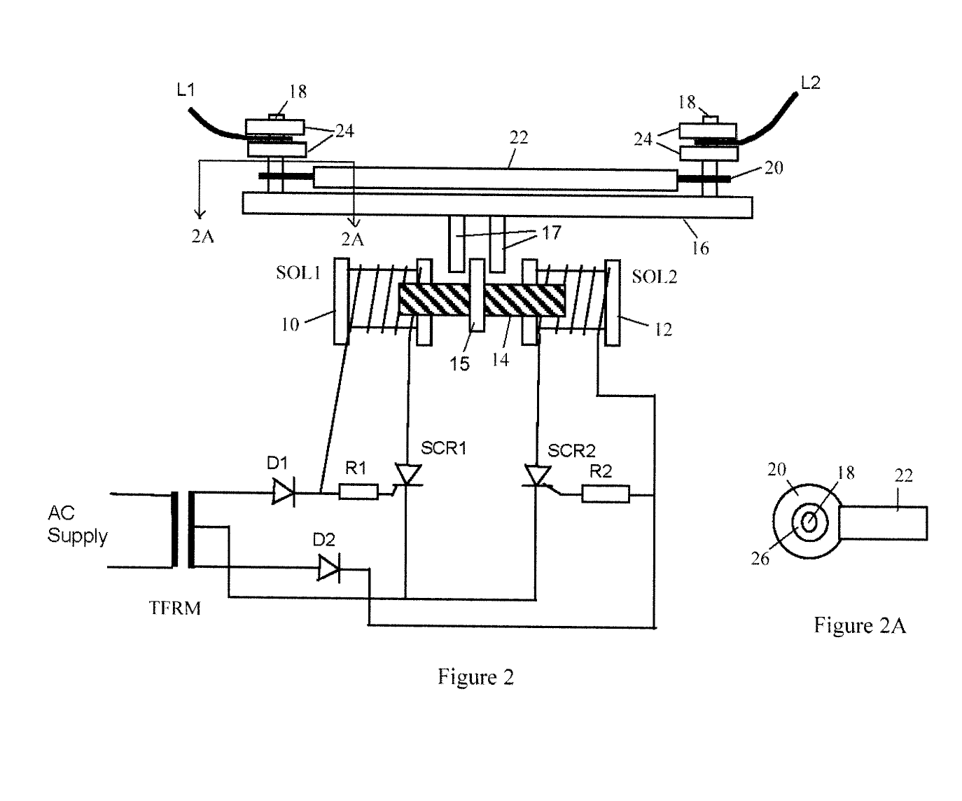

Referring to FIG. 2, the arc generator comprises two electromagnetic solenoids SOL1, SOL2 wound on respective hollow bobbins 10, 12 aligned on a common axis, the solenoids sharing a common ferromagnetic plunger 14 slidable axially in the bobbins. Above the plunger 14 there is an insulated sliding plate (slider) 16 to which are secured two electrically conductive studs 18. A respective annular terminal 20 is placed freely over each stud 18, the terminals 20 being fitted to opposite ends of a rigid cable 22. The terminals 20 are prevented from coming off the studs 18 by nuts 24 which also connect respective electrical leads L1 and L2 to the two studs.

The diameter of the aperture in each terminal 20 is just slightly larger than the diameter of the respective stud 18 so as to create a small gap 26 between the terminal and the stud, FIG. 2A, such that when the cable 22 is centrally positioned between the two studs 18 it is electrically isolated from both. Each stud 18 and its associated terminal 20 therefore constitutes a pair of contacts forming a loose electrical connection. As a result the cable is free to move a short distance longitudinally and laterally relative to the two studs. The leads L1 and L2 are connected back to the AC mains supply via a load (not shown) such that if the terminals 20 were touching each stud 18 simultaneously a predetermined load current would flow through the cable.

Each solenoid SOL1, SOL2 is connected to a supply derived via diodes D1 and D2 and a mains transformer TFMR from the ac mains. The transformer provides isolation from the AC mains supply and may also be used to change the secondary voltage to any convenient value. The secondary winding of the transformer TFRM has a centre tap to provide a common connection for two electronic switches in the form of silicon controlled rectifier SCR1 and SCR2.

When the mains supply is turned on each silicon controlled rectifier will conduct alternately for up to one half cycle of the mains supply and when SCR1 is turned on SOL1 will be energised during which time SCR2 will not be conducting and SO12 will not be energised. As a result the plunger 14 will initially be drawn into the bobbin 10 and, via a collar 15 on the plunger which extends between two limit stops 17 on the slider, the plunger will pull the slider 16 in the same direction as the plunger. When SCR1 turns off at the end of a half cycle SCR2 will turn on and the plunger 14 will be drawn in the opposite direction into the bobbin 12, pulling the slider 16 also in the opposite direction.

The two solenoids will conduct on alternate half cycles of the mains supply at the supply frequency, for example 50 Hz, and as a result the slider 16 will oscillate back and forth at this frequency. The cable 22 will thus be thrown back and forth between the two studs 18 and this will cause arcing between each cable terminal 20 and its respective stud 18 as the cable vibrates rapidly between the two studs alternately opening and closing the pair of contacts 18,20 at each end. The arcing current will occur predominantly at the mains supply frequency and its magnitude will be determined by the current setting load connected via the leads L1 and L2. Thus an arcing current of a precise magnitude and frequency can be generated by the arc generator shown in FIG. 2.

This arc generator can be connected on the load side of an AFD, for example via a protected socket outlet, and it will generate genuine arcing currents which will enable the AFD to be tested. The arcing current can be selected by suitable choice of the current setting load within the generator to ensure that the current is greater than the minimum threshold of detection for an AFD. This is presently 5A for AFDs based on UL1699. With the arrangement of FIG. 2, the arcing current will always be produced at the mains supply frequency of the AFD being tested, e.g. 50 Hz or 60 Hz, thus ensuring that the AFD operation is verified at its actual operating frequency and not at some arbitrary or artificially generated frequency.

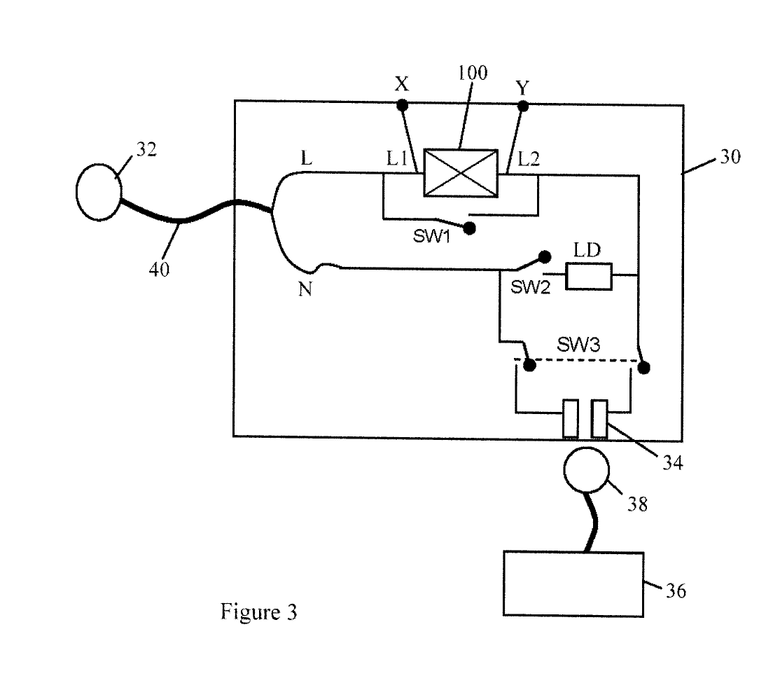

FIG. 3 shows an embodiment of the invention in the form of a portable AFD tester incorporating the arc generator shown in FIG. 2.

The apparatus shown in FIG. 3 comprises an external housing 30 having a mains plug 32 on a flying lead 40 for plugging into the ac mains and a mains socket 34 set into the wall of the housing. The plug 32 is connected to supply ac power to the socket 34 via live and neutral electrical supply conductors L, N inside the housing. The socket 34 allows an external appliance 36 having a mains plug 38 to be plugged into the housing for receiving power from the plug 32 through the internal supply conductors L, N.

An arc generator 100 as shown in FIG. 2 is mounted inside the housing 30, the leads L1 and L2 being connected in series between the plug 32 and the socket 34 in the supply conductor L. (The transformer TRFM is connected inside the housing to the mains conductors L and N, but this is not shown in FIG. 3).

Various switches SW1, SW2 and SW3 inserted in the internal circuitry of the housing 30 are manually operable from outside the housing for enabling a plurality of different arc fault tests to be made. The switch SW1 allows the user to selectively shunt the arc generator 100, the switch SW2 allows the user to selectively connect an internal load LD, and the switch SW3 allows the user to selectively isolate the socket 34.

In use the tester is plugged into an AFD-protected mains socket using the plug 32. The tester may have an on-off switch and when the tester is powered from the mains supply and SW1 is open and SW2 is closed an arcing current will flow through the internal current setting load LD as previously described. As the current is flowing in a series circuit, this represents a series arc fault condition. This current can be set at the lowest threshold of detection of the AFD, e.g. 5A, to verify that the AFD is still able to operate correctly within its specified level.

When SW1 and SW2 are open and SW3 is closed and an external load such as an electrical appliance 36 is connected to the socket 34, arcing current will flow through the external load, and provided this current is above the minimum operating threshold of the AFD, the device should trip. In this way it can be verified that the AFD detects arcing currents with different loads, e.g. vacuum cleaners, etc.

If SW1 is closed and SW2 is open and a range of appliances is connected to the socket 34, the AFD should not trip because no arc fault exists. In this way the AFD can be tested via the AFD tester to ensure that the device is not prone to nuisance tripping. If SW2 is then closed followed by opening of SW1, thus simulating a series arc fault, the AFD should trip. If it fails to trip it will indicate that the load is masking the arcing current signature and preventing its detection. It should be noted that with SW1 open, SW2 and SW3 closed and an external load connected to socket 34, testing under a parallel arc fault condition can be made.

It would be possible to use the tester to test an AFD on a DC system, for example a photovoltaic solar panel, by arranging for connections L1 and L2 to be made accessible in the form of externally accessible terminals for connecting in series with the DC supply, for example as shown at X and Y in FIG. 3. The AFD tester would need to be connected to any convenient AC supply, but would produce series arcing as previously described.

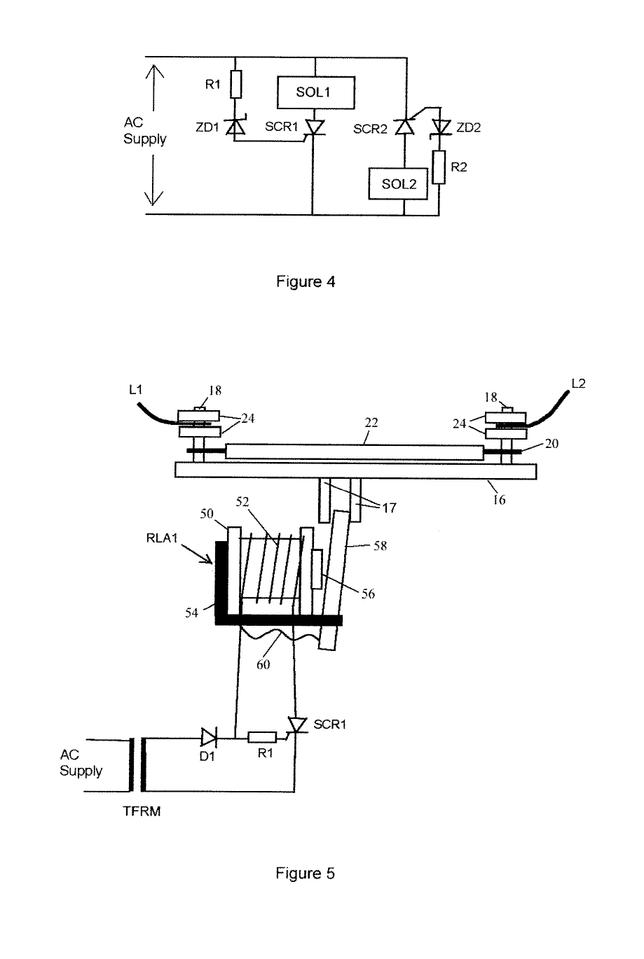

FIG. 4 shows an alternative arrangement for energising the solenoids SOLI and SOL2 of FIG. 2. In this arrangement SOL1 and SOL2 are connected to the mains supply via SCR1 and SCR2 which are connected in a parallel inverse arrangement. SCR1 will conduct and energise SOL1 on positive half cycles of the mains supply and SCR2 will energise SOL2 on negative half cycles of the mains supply. ZD1 and ZD2 may be included to set a time interval or an actuating voltage level at which the associated SCR turns on after each zero crossover.

The AFD tester can be refined or improved without departing materially from the invention. For example, the use of electronic switches SCR1 and SCR2 controlled by the mains supply frequency obviates any need for calibrating the arc current frequency. However the arcing frequency could be set by use of an oscillator instead of SCR1 and SCR2. Lights could be fitted to indicate current flow, and a single electromagnet may be used, etc.

FIG. 5 shows an alternative to the solenoid arrangement of FIG. 2, using a single solenoid.

In this arrangement an electromechanical relay RLA1 comprises a bobbin 50 with a solenoid winding 52, a frame 54, a pole piece 56 and a ferromagnetic armature 58 which is pivoted to the frame 54 and biased to an open position (i.e. away from the pole piece 56) by a spring 60. On each positive half cycle of the mains supply the solenoid 52 is energised and the armature 58 is pulled toward the pole piece 56. On negative half cycles the armature 58 moves to its open position under the action of the spring 60 because the solenoid 52 is de-energised. The armature 58 is used to vibrate the slider 16 back and forth and generate arcing as previously described.

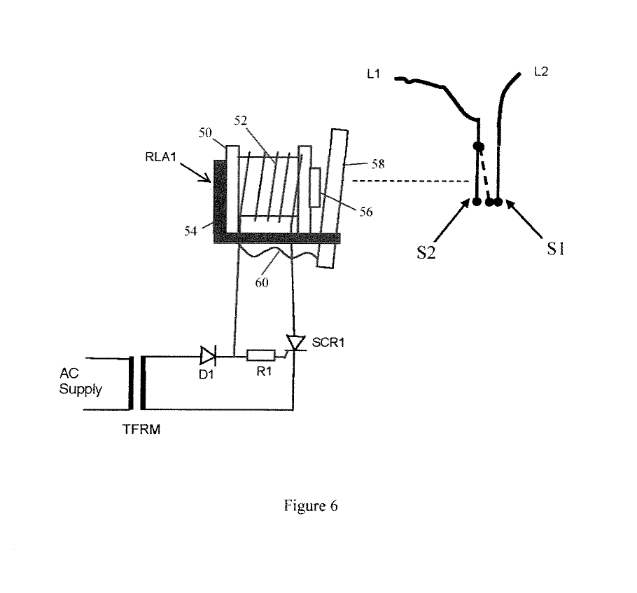

FIG. 6 shows an alternative construction for the arc generator 100 in FIG. 3.

In this arrangement the relay RLA1 of FIG. 5 is shown with one set of contacts, a fixed contact S1 and a movable contact S2 mechanically coupled to the armature 58. The contact S1 is biased away from the contact S2, so the contacts are normally open. As the armature 58 vibrates back and forth on positive and negative half cycles of the mains supply, as described for FIG. 5, the contacts S1, S2 will vibrate open and closed alternately, thus making and breaking the current flow from L1 to L2 on each half cycle of the mains supply. This arrangement obviates the need for separate arcing means such as the slider arrangement of FIG. 2.

With this arrangement a standard relay can be used, and it can be replaced after a certain number of operations when the contacts have deteriorated to an unacceptable extent.

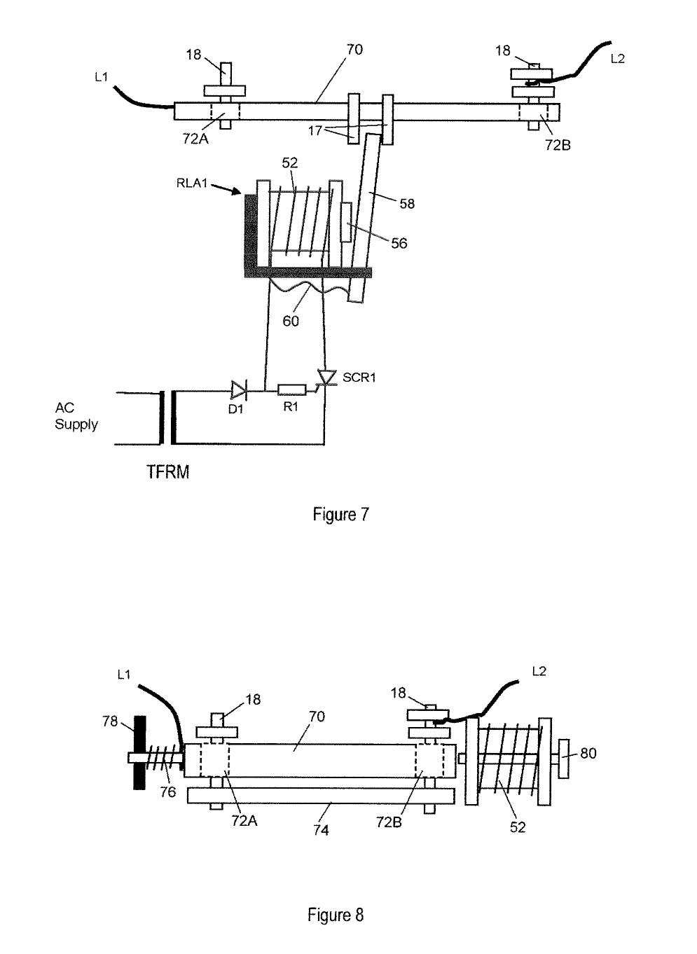

FIG. 7 shows still another construction for the arc generator 100 in FIG. 3.

FIG. 7 is a modification of FIG. 5 and the drive mechanism for the armature 58 is the same. Thus, as previously described, on each positive half cycle of the mains supply the relay RLA1 is energised and the armature 58 is pulled toward the pole piece 56, and on negative half cycles the armature 58 moves to its open position under the action of the spring 60. However, in this case the cable 22 is replaced by a solid conductive bar 70 having slots 72A, 72B at each end which loosely fit over the conductive studs 18, the bar 70 being supported for sliding movement by an insulating support, not shown. The first supply lead L1 is connected directly to one end of the bar, and the second supply lead is connected to the conductive retaining stud 18 at the opposite end of the bar, as in the case of FIG. 5.

The armature 58 is used to directly vibrate the conductive bar 70 back and forth such that the slot 72B in the bar causes rapid intermittent connections between the bar and the right hand (as seen in FIG. 7) stud 18, with resulting arcing.

FIG. 8 shows yet another construction for the arc generator 100 in FIG. 3 which, like FIG. 7, also uses a directly-driven conductive bar 70.

In FIG. 8, the conductive bar 70 is slidably mounted on an insulating support 74. A compression spring 76 acting against an end stop 78 biases the bar 70 towards a first position (right hand side as shown in FIG. 8). The biasing spring also retains the first supply lead L1 in contact with that end of the bar, but this lead could be connected directly to the bar as in FIG. 7. However by connecting it as shown, L1 does not impede the movement of the bar. A solenoid 52 is positioned at the opposite end of the bar 70. Two conductive studs 18 loosely enter slots 72A, 72B as in FIG. 7. The right hand side stud 18 has the outgoing supply lead L2 connected to it. When the solenoid 52 is energised its plunger 80 will push the bar 70 laterally to a second (left hand side) position, and when the solenoid is de-energised the bar will return to the first position because of the biasing spring. The process of energisation and de-energisation is done at mains frequency by a drive circuit which is not shown but which is the same as that shown in FIGS. 5 and 7. The rapid making and breaking of the flow of current at the conducting stud 18 will result in arcing at this point.

This arrangement offers several advantages over previous embodiments, such as its simplicity, concentrating of arcing at one point so as to facilitate optimisation of arcing, etc. Another advantage is that, because the spring 76 will hold the bar 70 in contact with the right hand stud 18 when the arc generator is not in use, the available arcing current will flow through the circuit prior to commencement of the arcing and thereby facilitate measurement and verification of the available arcing current.

A timer could be included in the tester to limit the duration of arcing current flow at each operation. The tester could be fitted with a counter to alert the user to replace the relay or cable after a certain number of operations. A relay with an AC or DC coil could be used. A shading ring is fitted to AC relays to prevent them from chattering, but if the shading ring was removed the inherent chatter could be used to generate the arcing current. Under such an arrangement the relay could be operated directly from the mains supply if its coil was suitably rated.

In the examples above, the symmetry of the arcing current will be to some extent determined by the phase within each half cycle at which conduction of the electromagnetic means commences. However some degree of asymmetry and randomness can be introduced into the arcing current by allowing relay chatter or by overdriving the relay or solenoid coil such that the mechanical action ceases to be in synch with the electrical energisation cycles. Asymmetry and randomness may be also be achieved by driving the SCRs from an alternative source, for example a randomly variable signal generator, etc.

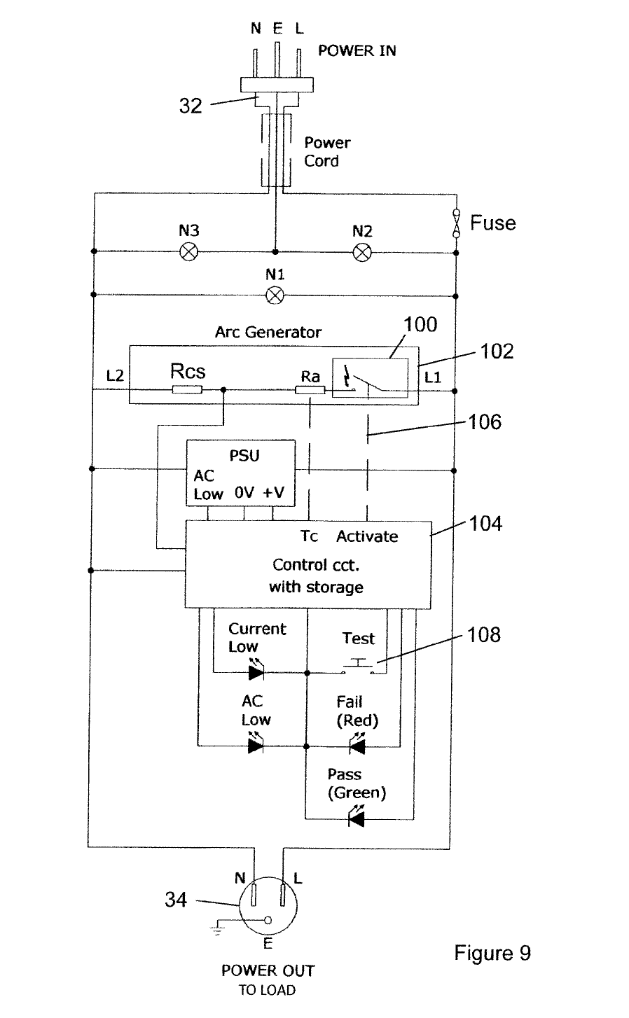

FIG. 9 is a circuit diagram of an apparatus according to a further embodiment of the invention, designed to simulate a parallel arc fault.

As before, the apparatus comprises a power in plug 32 and a power out socket 34 with live L and neutral N supply conductors L, N extending between them for the supply of AC power at the plug 32 to a load connected to the socket 34. It will be understood that, although not shown, the conductors L, N and the other circuitry shown in FIG. 9 between the plug 32 and the socket 34 is contained in an insulating housing 30 as for the circuitry of FIG. 3.

In this case the arc generator 102 is connected across the supply conductors L, N inside the housing 30 to simulate a parallel arc fault. The arc generator 102 comprises a basic arc generator 100 as shown in any one of FIGS. 2 and 4 to 8 driven by the AC supply via a transformer TRFM, and further includes a resistor Ra in series in the lead L2 to set the maximum arcing current. The lead L2 may also include a current sense resistor Rcs in the case where the device 100 is of a kind (e.g. FIG. 8) in which the available arcing current will flow through the arc generator 100 prior to commencement of the arcing. The connection of the arc generator 100 to the supply via the transformer TRFM is not shown to avoid overcomplicating the drawing.

The arc generator 100 is activated by a control signal issued by an electronic control circuit 104 on a control line 106 when a test button 108 on the exterior of the housing 30 is pressed. The control signal on line 106 closes a normally open switch (not shown) in the arc generator drive circuit.

The control circuit 104 monitors the mains supply voltage and measures the available test current at Rcs before the arc generator is activated by pressing the test button 108. A power supply unit PSU provides power to the control circuit 104. If the supply voltage is below a certain level the available test current will be too low to enable a valid test to be done, in which case an “AC Low” indicator LED will be lit. If the available test current is too low, for example because of an open circuit or high impedance in the arc generating circuit, a “Current Low” indicator LED will be lit.

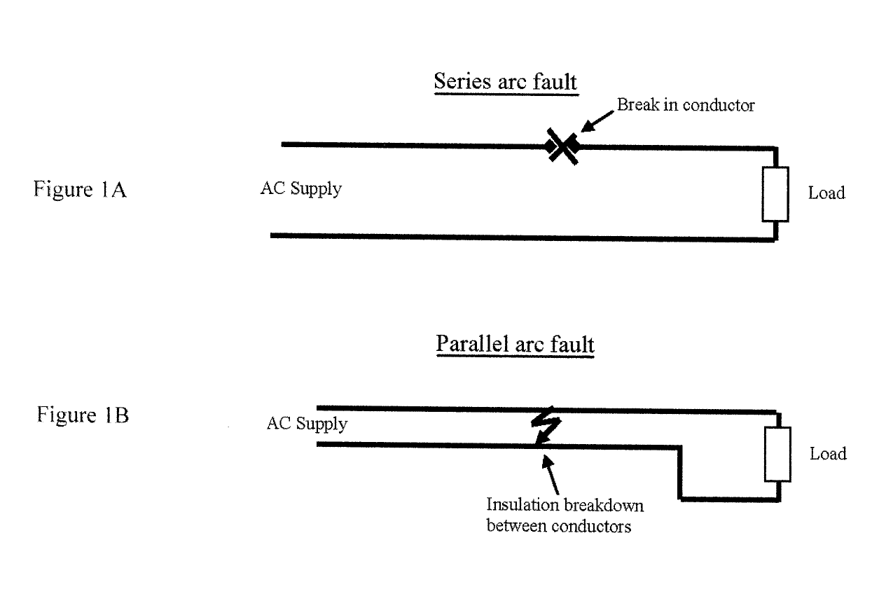

When the arc generator 100 is activated by pressing the test button 108, it will generate a parallel current representative of that shown in FIG. 1B. This will occur whether or not an external load is connected. If an upstream AFD under test passes the test, a green “PASS” LED indicator will be lit. This will indicate that the AFD tripped within a certain period during the test. If the AFD fails the test, a red “FAIL” indicator LED will be lit.

The control circuit 104 preferably incorporates a timer to limit the duration of the flow of arcing current, and also to set a certain interval between repeated tests so as to reduce the risk of overheating or damage to the tester. The arc generator preferably includes a temperature sensor Tc which will detect excessive heat in the resistor Ra and enable the control circuit to inhibit further testing until the temperature has reached a safe level.

When an upstream AFD trips, power will be removed from the tester. However, by suitable storage of power, e.g. in a capacitor or in a battery, the result of the test can continue to be indicated for a certain period after the test.

The status of supply Line, Neutral and Earth are monitored by indicators N1, N2 and N3. When the supply connections are correct, indicators N1 and N2 will be lit and N3 will not be lit. In the event of loss of supply E, N2 will not be lit, but N1 and N3 will be lit, but possibly not at full brightness because they will share the supply voltage. In the case of loss of supply N, N2 will be lit at full brightness, and N1 and N3 will be lit, but not necessarily at full brightness because they will share the supply voltage. In the event of loss of supply L, no indicator will be lit.

Described herein is an AFD tester which produces realistic arc fault currents at the frequency of the protected AC circuit and which facilitates testing of the AFD for problems of nuisance tripping and masking.

Although the foregoing has described embodiments of AFD tester having an output socket 34 for connection of an external load, the output socket could be omitted if it were desired to have a simple AFD tester based only on the arc generator with no provision for connection of an external load.

The invention is not limited to the embodiments described herein which may be modified or varied without departing from the scope of the invention.

1. An apparatus for testing an arc fault detector, comprising a housing (30) having an ac power input device (32)connected to supply ac power to electrical conductors (L, N) inside the housing, and an arc generator (100) inside the housing connected to at least one of said conductors, the arc generator comprising at least one pair of contacts and means to vibrate said contacts alternately open and closed to generate arcing.

2. A device as claimed in claim 1, wherein the arc generator (100) comprises a loose electrical connection (18, 20) and means to vibrate said connection.

3. A device as claimed in claim 2, wherein the means to vibrate said connection comprises a mechanical oscillator operated by at least one electromagnetic winding.

4. A device as claimed in claim 3, wherein said mechanical oscillator comprises two electromagnetic windings (SOL1, SOL2) which are energised alternately to drive a ferromagnetic member (14) alternately in opposite directions.

5. A device as claimed in claim 3, wherein said mechanical oscillator comprises an electromagnetic winding (52) which is intermittently energised to drive a ferromagnetic member (58) in one direction and a resilient device (60) to return the ferromagnetic member (58) in the opposite direction between successive energisations of the electromagnetic winding (52).

6. A device as claimed in claim 1, wherein the arc generator (100) comprises a pair of contacts (S1, S2) which are caused to vibrate alternately open and closed by repeated energisation of an electromagnetic winding (52).

7. A device as claimed in any preceding claim, wherein the arc generator (100) is connected in series with one of the conductors (L) inside the housing to simulate a series arc fault.

8. A device as claimed in any one of claims 1 to 6, wherein the arc generator (100) is connected across a pair of conductors (L, N) inside the housing to simulate a parallel arc fault.

9. A device as claimed in any preceding claim, wherein the vibration means is driven by the mains supply so as to vibrate the contacts at the supply frequency.

10. A device as claimed in any preceding claim, wherein the housing has externally accessible terminals (X, Y) and the arc generator is also connected across said terminals.

11. A device as claimed in any preceding claim, wherein the power input device (32) comprises an electrical plug.

12. An apparatus as claimed in any preceding claim, the housing further having an output device (34) allowing connection of an external appliance (36) for receiving power from the input device (32) through the internal conductors.

13. A device as claimed in any claim 12, wherein the power output device (34) comprises an electrical socket.
